(19) United States
(12) Patent Application Publication
(10) Pub. No.: US 2009/0078572 A1
(43) Pub. Date: Mar. 26, 2009

(54) MAGNETRON END-BLOCK WITH SHIELDED TARGET MOUNTING ASSEMBLY

(75) Inventors: Hans-Juergen HEINRICH, Grossroehrsdorf (DE); Goetz Grosser, Dresden (DE); Thorsten Sander, Dresden (DE); Ulf Seyfert, Dresden (DE)

Correspondence Address: HESLIN ROTHENBERG FARLEY & MESITI PC, 5 COLUMBIA CIRCLE, ALBANY, NY, 12203, US

(73) Assignee: VON ARDENNE Anlagentechnik GmbH, Dresden (DE)

(21) Appl. No.: 12/236,816

(22) Filed: Sep. 24, 2008

(30) Foreign Application Priority Data
Sep. 24, 2007 (DE) 10 2007 045 714.8

(51) Int. Cl. C23C 14/35

(52) U.S. Cl. 204/298.22

(57) ABSTRACT

A magnetron arrangement includes an end block, which has a target fastening device for rotatable coupling of a tubular target, a holding device for a magnet system arranged in the interior of the tubular target and a shield, which covers the end of a tubular target mounted in the target fastening device. An area of the shield covering the end of the tubular target is configured, so that an annular gap remaining between the target support tube and the shield, viewed from the outside, has at least one radially outward-leading section.

The invention concerns a magnetron arrangement with a magnetron end block with shielded targeted fastening device. Magnetrons with a rotatable tube target ordinarily consist of the main components target tube (or tube target), end block and magnet arrangement. The target tube is connected on the front, for example, by means of a target-clamping device, on each side to a magnetron end block. The tubular target, which includes a support tube with a target material, plasma-sprayed, bonded or applied by melting, for example, cast, onto the outer surface, is mounted to rotate in this target clamping device or other target fastening device. The tube target, however, can also consist of one piece; in this case, the target tube is a component of the target material. A magnet arrangement fastened to a support provided for this purpose or another holding device, which generates the magnetic field required for plasma focusing, is situated in the interior of the tubular target.

In the sense of optimal utilization of the target material, the magnetic field is brought close to the target-fastening device situated on the faces of the target tube, for example, a target-clamping device. Such a target-clamping device can include, for example, a support flange 21, a clamping ring 22 and a tightening ring 23. Owing to the fact that the target and the end block body have different electrical potential, both are functionally insulated from each other. The end block body is expediently enclosed with a coating protective device, which, however, must not touch the current-conducting target. In order to protect the target fastening device and end block body from undesired coating, as well as parasitic plasmas, connection of the target tube to the end block body is protected in the region of the target fastening device by means of a shield, an additional so-called coating protective device. This shield prevents stray vapor from bridging the insulation between the target fastening device and the shield, and between the target fastening device and the end block body.

The shield is ordinarily configured, so that an annular gap between the target fastening device and shield or the target material and shield prevents penetration of stray vapor.

A shield is known from U.S. Pat. No. 5,213,672, which is designed as a hollow cylinder and encloses one end of the tube target, so that an annular gap remains between the shield and the tube target, an additional hollow cylindrical insulator being arranged within the annular gap.

To avoid arcing, which can develop over the outside of such a hollow cylindrical shield, it is proposed in U.S. Pat. No. 5,527,439 to provide an annular structure on the outside of the shield, for example, a continuous groove.

Additional hollow cylindrical shields are known from U.S. Pat. No. 5,725,746, variants also being proposed, in which the shield extends around an end section of the tube target that is tapered relative to the sputter zone (FIG. 5), or in which the outside diameter of the tube target right in front of the shield has an outside diameter increased relative to the sputter zone (FIG. 6), so that the first section (from the standpoint of stray vapor particles) of the gap remaining between the tube target and shield extends radially to the axis of rotation and symmetry of the tube target.

Hollow cylindrical shields are again proposed in US 2005/0051422 A1, which, however, do not extend beyond the fastening device on the end block side.

A shortcoming in the previous designs is the fact that, because of the high heat load from the plasma into the edge area of the tube target, the configuration of the target fastening device and the shield cannot be optimally designed to meet their function. Only an insufficient annular gap that seals against penetration of stray vapor is obtained. This annular gap also has a simple hollow cylindrical shape, i.e., stray vapor can penetrate through the annular gap in the axial direction into the interior of the shield. The design of a shield with a radially extended first section of the gap between the shield and tube target, as described above, is also unfavorable in this respect.

A task of the present invention is to configure the target, the clamp and the shield of the insulated area on the end block, so that long process times are achieved with maximum electrical process power and without influencing utilization of the target material.

Individual elements of the invention can be described, in that the interfering influences relative to known solutions are farther separated from each other physically or/and the two end blocks are positioned far enough from each other, so that the forming plasma does not have a thermally increased effect on the shield or/and the support tube of the tubular target, and the target material applied to it is strongly reduced in diameter or/and the shield is configured conically toward the target material and an annular gap is made narrow and meandering.

One possible step to solve the existing problem is not to occupy the end of the target tube with target material, i.e., to increase the distance between the target fastening device or the shield enclosing the target fastening device and the target material arranged on the target tube. As an alternative, the target material can be laid out in the end areas of the target support tube with reduced diameter, so that the sputter attack has an effect essentially on the area of the target material with the larger diameter, but undesired atomization of the material of the target support tube is prevented.

Another possible step consists of configuring the tube target, so that there is a distinct difference between the outside diameter of the target support tube and the outside diameter of the target material applied to the target tube, and the inside diameter of the visible opening of the shield enclosing the target support tube is chosen, so that this opening encloses the target support tube, not occupied on its ends with target material, as narrowly as possible. In the case of target material, designed as described above in the end areas of the target support tube with limited diameter, this corresponds to a design with a distinct difference between the outside diameter of the target material and the end areas and the outside diameter of the target material in the sputter zone, the inside diameter of the opening of the shield being chosen, so that this opening encloses the target material in these end areas as narrowly as possible.

Penetration of stray vapor into the interior of the shield can be significantly reduced or prevented on this account, so that the annular gap existing between the target fastening device and the end of the tube target, on the one side, and the shield, on the other side, is no longer configured simply linearly, like a hollow cylinder, but instead is made meandering or in the fashion of a labyrinth seal, i.e., with at least one axially running and at least one radially running section.

A magnetron arrangement is therefore proposed, which comprises an end block, which has a target fastening device for rotatable coupling of a tubular target, a holding device for a magnet system arranged in the interior of the tubular target, and a shield, which covers the end of a tubular target positioned in the target fastening device, in which the area of the shield covering the end of the tubular target is designed, so that the annular gap remaining between the tubular target and the shield, viewed from the outside, has at least one radially outward-leading section, i.e., a section directed outward radially from the tube axis.

“Viewed from the outside” then means a point of view that corresponds to a view of the annular gap from the position of a stray vapor particle that reaches the annular gap. If, for example, in connection with a first section of the annular gap running axially toward the target support tube, a second section is connected, which leads radially outward, further movement of the stray vapor particle through the annular gap is significantly hampered, since this direction of movement is directed opposite the original direction of movement of the stray vapor particle before entering the annular gap. The limitation of the annular gap formed by the outer surface of the target support tube or the target material or the target fastening device and the inside surface of the shield removes energy from the penetrating stray vapor particle, so that it can no longer penetrate into the annular gap. A radially outward-leading section of the annular gap is then understood to mean not only sections directed vertically to the rotational axis of the target, but also those sections that run obliquely to the axis of rotation, since these sections also delay movement of the stray vapor particles through the annular gap and ultimately suppress them.

In one embodiment, the annular gap remaining between the tubular target and the shield, viewed from the outside, is also provided with at least one radially inward-leading section, i.e., directed radially from the outside to the tube axis. Because of the renewed reversal of direction of particle movement, additional energy can be removed from stray vapor particles that might still overcome the radially outward-leading section of the annular gap, because of the higher kinetic energy.

The proposed features of the shield and the resulting annular gap can be achieved, in terms of design, in that the outside diameter of the target fastening device is greater than the inside diameter of the opening of the shield enclosing the target support tube or the target material. In this way, the shield, viewed from the end block, overlaps the target-fastening device in claw-like fashion. It can therefore be useful to design the shield in two parts with an axially running separation plane, so that assembly and disassembly of the shield is simplified relative to a one-piece version.

It can also be designed so that the outside diameter of the target material is greater than the inside diameter of the opening of the shield enclosing the target support tube or the target material arranged in the end area of the tubular target. Through this provision, the ablation process during sputtering occurs with a radial distance to the annular gap, so that the probability that a stray vapor particle will reach the entry area of the annular gap is already reduced on this account. In addition, the tubular target can be configured, so that the end areas of the target support tube are free of target material, so that the sputter zone also has a spacing to the shield in the axial direction. In this case, it can also be useful to design the magnet system shortened in the interior of the tube target, so that the plasma only burns above the target material and the ends of the target support tube are not exposed to any sputter attack.

In a corresponding design embodiment with several alternating radially inward and outward-leading sections, which can optionally be connected to each other by axial sections, a situation can be achieved in which the outer surfaces of the target fastening device and the end of the tubular target mounted in it, on the one hand, and the inside surface of the shield, on the other hand, are spaced from each other by a meandering annular gap.

This annular gap can advantageously have such a limited gap dimension, that it forms a labyrinth seal, through which penetration of stray vapor particles is reliably prevented, so that no stray vapor reaches the end block.

In another embodiment, it can be proposed that the outside of the area of the shield enclosing the end of the tubular target be designed conically.

The proposed magnetron arrangement is further explained below by means of a practical example and a corresponding drawing. The single

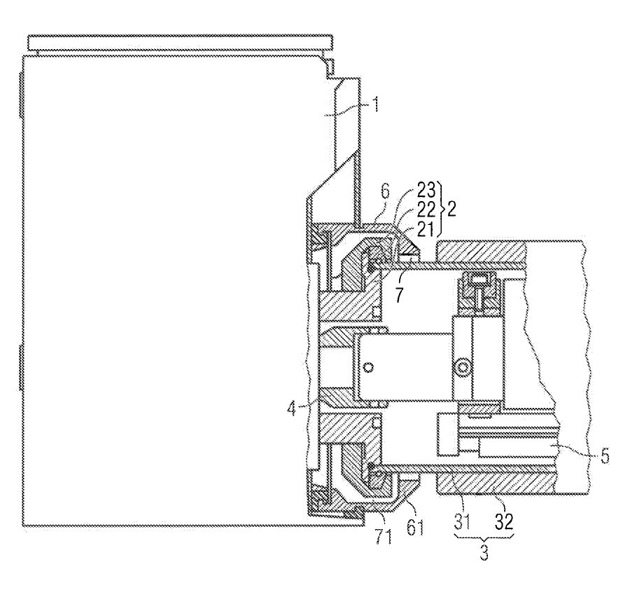

FIG. 1 shows a longitudinal section through an end block and the end area of the tube target fastened to it.

The end block 1 includes, in known fashion, a housing, which is designed for vacuum-tight connection with a chamber wall of a vacuum coating installation. The end block 1 serves for rotatable mounting of the tubular target 3, which includes a target support tube 31, as well as the target material 32 arranged on the outer surface of the target support tube 31, as well as the support of the magnet system 5 arranged on the interior of the target support tube 31.

The end block 1 also includes a rotatable hollow shaft with a support flange 21, which, in this practical example, forms a target fastening device 2 together with a clamping ring 22, releasably fastened to the target support tube 31, and a tightening ring 23 that encloses the support flange 21 and the clamping ring 22 and connects them. The magnet system 5 is fastened to the holding device 4, which is guided through the hollow shaft of the target-fastening device 2, so that the magnet system 5 can be at rest when the tube target 3 is rotated.

A shield 6 is also fastened on the end block 1, which encloses the target-fastening device 2 and the end of the tubular target 3 in claw-like fashion. The outside 61 of the area of shield 6 enclosing the end of the tubular target 3 is designed conically. The outside diameter of the target fastening device 2 is greater than the inside diameter of the opening 7 of the shield 6 enclosing the target support tube 31, and the outside diameter of the target material 32 is greater than the inside diameter of the opening 7 of the shield 6 enclosing the target support tube 3. The target material 32 and the magnet system 5 are also configured, so that the sputter zone has a distinct axial spacing to the end of the target support tube 31 and the end block 1.

The annular gap remaining between the shield 6 and the target support tube 31 or the target fastening device 2, viewed from the outside, in this sequence has a first, axial section, a second, radially outward-leading section, a third, axial section, as well as a fourth, radially inward-leading section. This practical example is configured comparatively simply; naturally, it would also be possible to provide additional sections, in order to finally reach a meandering configuration of the annular gap 71.

### Magnetron Arrangement with Shielded Target Holder

List of reference numbers

| | |
|---|---|
| 1 | End block |
| 2 | Target fastening device |
| 21 | Support flange |
| 22 | Clamping ring |
| 23 | Tightening ring |
| 3 | Tubular target |
| 31 | Target support tube |
| 32 | Target material |
| 4 | Holding device |
| 5 | Magnet system |
| 6 | Shield |
| 61 | Outside |
| 7 | Opening |
| 71 | Annular gap |

1. Magnetron arrangement, comprising an end block having a target fastening device for rotatable coupling of a tubular target, a holding device for a magnet system arranged in an interior of the tubular target and a shield that covers an end of the tubular target an area of the shield covering the end of the tubular target being configured, so that an annular gap remaining between the tubular target and the shield, viewed from the outside, has at least one radially outward-leading section.

2. Magnetron arrangement according to claim 1, wherein the annular gap remaining between the tubular target and the shield, viewed from the outside, also has at least one radially inward-leading section.

3. Magnetron arrangement according to claim 1 wherein an outside diameter of the target fastening device is greater than an inside diameter of an opening of the shield enclosing the tubular target.

4. Magnetron arrangement according to claim 1, wherein the tubular target includes target material and an outside diameter of the target material is greater than an inside diameter of an opening of the shield enclosing the tubular target.

5. Magnetron arrangement according to claim 1, wherein an outer surface of the target fastening device and the end of the tubular target is spaced from an inside surface of the shield by a meandering annular gap.

6. Magnetron arrangement according claim 5, wherein the annular gap forms a labyrinth seal.

7. Magnetron arrangement according to claim 1, wherein an outside of the area of the shield enclosing the end of the tubular target is configured conically.
